(19) United States
(12) Patent Application Publication
(10) Pub. No.: US 2024/0217845 A1
(43) Pub. Date: Jul. 4, 2024

(54) WATER TREATMENT SYSTEM

(71) Applicant: KYUNGDONG NAVIEN CO., LTD., Pyeongtaek-si (KR)

(72) Inventors: Soo Young Lee, Seoul (KR); Young Jo Lim, Seoul (KR); Gwang Hee Cho, Seoul (KR)

(21) Appl. No.: 18/543,602

(22) Filed: Dec. 18, 2023

(30) Foreign Application Priority Data
Dec. 29, 2022 (KR) 10-2022-0189869

(51) Int. Cl. C02F 1/42; C02F 1/00

(52) U.S. Cl. CPC C02F 1/42; C02F 1/001

(57) ABSTRACT

According to an aspect of the present disclosure, a water treatment system includes a first filter unit and a second filter unit that selectively perform any one of a removal mode of removing at least a portion of an ionic material included in supplied raw water based on an electrical force to discharge soft water including less ionic material than the raw water, and a regeneration mode of discharging the ionic material collected in the removal mode together with the supplied raw water to discharge regeneration water including the ionic material more than the raw water.

### CROSS-REFERENCE TO RELATED APPLICATION

This application claims the benefit of priority to Korean Patent Application No. 10-2022-0189869, filed in the Korean Intellectual Property Office on Dec. 29, 2022, the entire contents of which are incorporated herein by reference.

### TECHNICAL FIELD

The present disclosure relates to a water treatment system.

### BACKGROUND

A water treatment system is a system that produces soft water from raw water and supplies it to a source of demand. For example, in a points of entry (PoE) type water treatment system, the source of demand may be a house, and the soft water delivered to the source of demand is delivered to faucets, shower heads, or the like, which requires use of water.

A filter that converts raw water into soft water by removing ionic material from raw water cannot be used permanently, and even a filter that may be used semi-permanently may be smoothly used only when a regeneration operation of discharging the collected ionic material together with the water has to be performed periodically.

According to the water treatment system that performs a regeneration operation, when an amount of the ionic material that may be removed in a filter is exceeded, regeneration water is discharged to an outside and the ionic material may be additionally removed by using newly supplied raw water. For example, a soft water system may additionally perform a drainage operation to discharge the regeneration water to an outside to prevent the ionic material from being supersaturated in the filter during the regeneration operation.

However, when water is discharged to the outside during the regeneration operation while the amount of the ionic material that may be removed by the filter is not considered, an amount of water discarded during the regeneration operation may increase. For example, when the water treatment system performs a drainage operation without considering a capacity of the filter in spite that the filter may remove a sufficient amount of ionic material, the amount of discarded water may unnecessarily increase.

### SUMMARY

The present disclosure has been made to solve the above-mentioned problems occurring in the prior art while advantages achieved by the prior art are maintained intact.

An aspect of the present disclosure provides a water treatment system that decreases an amount of water that is unnecessarily discarded.

The technical problems to be solved by the present disclosure are not limited to the aforementioned problems, and any other technical problems not mentioned herein will be clearly understood from the following description by those skilled in the art to which the present disclosure pertains.

According to an aspect of the present disclosure, a water treatment system includes a first filter unit and a second filter unit that selectively perform any one of a removal mode of removing at least a portion of an ionic material included in supplied raw water based on an electrical force to discharge soft water including less ionic material than the raw water, and a regeneration mode of discharging the ionic material collected in the removal mode together with the supplied raw water to discharge regeneration water including the ionic material being more than the raw water, a first soft water discharge passage and a second soft water discharge passage that discharge the soft water from the first filter unit and the second filter unit, and a source-of-demand passage, in which the first soft water discharge passage and the second soft water discharge passage are integrated, a first regeneration water discharge passage and a second regeneration water discharge passage that discharge the regeneration water from the first filter unit and the second filter unit, a first regeneration valve and a second regeneration valve disposed in the first regeneration water discharge passage and the second regeneration water discharge passage, and that adjusts a discharge amount of the regeneration water, a flow amount sensor disposed in the source-of-demand passage to measure a flow amount of the soft water discharged from the first filter unit or the second filter unit, and a processor electrically connected to the first filter unit, the second filter unit, the first regeneration valve, the second regeneration valve, and the flow amount sensor, and when it is assumed that the first filter unit performs the removal mode and the second filter unit performs the regeneration mode for a first time period, the processor performs a control to close the second regeneration valve to interrupt flow of the regeneration water discharged through the second regeneration water discharge passage for a second time period being shorter than the first time period when a total amount of the soft water discharged in the removal mode shortly before the regeneration mode is performed is more than a reference value, and performs a control to close the second generation valve to interrupt the flow of the regeneration water discharged through the second regeneration water discharge passage for a (2-1)-th time period of the second time period and to open the second regeneration valve to allow the flow of the regeneration water for a (2-2)-th time period of the second time period when the total amount of the soft water discharged in the removal mode shortly before the regeneration mode is performed is less than the reference value.

As an example, the regeneration mode may include a retrieval operation that applies an electric voltage to one of the first filter unit and the second filter unit, which performs the regeneration mode, to supply the ionic material to the raw water, and a static operation of not applying the electric voltage to the one of the first filter unit and the second filter unit, which performs the regeneration mode, after the retrieval operation, and the retrieval operation may be performed for the second time period.

As an example, the processor may perform a control such that the second filter unit performs the static operation for a (3-1)-th time period being shorter than the second time period when the total amount of the soft water discharged in the removal mode shortly before the regeneration mode is performed is the reference value or less.

As an example, the water treatment system may further include a preparation operation of applying an electric voltage opposite to the electric voltage applied in the retrieval operation to the first filter unit and the second filter unit to remove at least a portion of the ionic material included in the raw water based on the electrical force, before switching to the removal mode after the static operation.

As an example, the processor may perform a control such that the second filter unit performs the preparation operation for a fourth time period being shorter than the (3-1)-th time period.

As an example, the processor may perform a control such that the second filter unit performs the static operation for a (3-2)-th time period being shorter than the second time period when the total amount of the soft water discharged in the removal mode shortly before the regeneration mode is performed is more than the reference value.

As an example, the regeneration mode may further include a preparation operation of applying an electric voltage opposite to the electric voltage applied in the retrieval operation to the first filter unit and the second filter unit to remove at least a portion of the ionic material included in the raw water based on the electrical force, before switching to the removal mode after the static operation.

As an example, the processor may perform a control such that the second filter unit performs the preparation operation for a fourth time period being shorter than the (3-2)-th time period.

As an example, the first filter unit and the second filter unit may alternately perform the removal mode and the regeneration mode every first time period.

As an example, a sum of the (2-1)-th time period and the (2-2)-th time period may be the same as the second time period.

As an example, the (2-2)-th time period may be shorter than the (2-1)-th time period.

### BRIEF DESCRIPTION OF THE DRAWINGS

The above and other objects, features and advantages of the present disclosure will be more apparent from the following detailed description taken in conjunction with the accompanying drawings:

FIG. 1 is a conceptual view of a water treatment system, in which a first filter unit performs a removal mode and a second filter unit performs a regeneration mode according to an embodiment;

FIG. 2 is a conceptual view of a water treatment system in which a first filter unit performs a regeneration mode and a second filter unit performs a removal mode according to another embodiment;

FIG. 3 is a conceptual view illustrating a principle of removing an ionic material in a CDI method;

FIG. 4 is a conceptual view illustrating a principle of electrode regeneration in a CDI method.

FIG. 5 is a voltage and time graph depicting an initial operation of a regeneration mode when an electric voltage is first supplied to a filter unit performing a regeneration mode;

FIG. 6 is a voltage and time graph of a second filter unit that performs a regeneration mode when a total amount of soft water discharged in a previous removal mode is a reference value or less; and

FIG. 7 is a voltage and time graph of a second filter unit that performs a regeneration mode when a flow amount of soft water discharged in a previous removal mode is more than the reference value.

### DETAILED DESCRIPTION

Hereinafter, embodiments of the present disclosure will be described in detail with reference to the accompanying drawings. In adding reference numerals to the components of the drawings, it is noted that the same components are denoted by the same reference numerals even when they are drawn in different drawings. Furthermore, in describing the embodiments of the present disclosure, when it is determined that a detailed description of related known configurations and functions may hinder understanding of the embodiments of the present disclosure, a detailed description thereof will be omitted.

Furthermore, in describing the components of the embodiments of the present disclosure, terms, such as first, second, “A”, “B”, (a), and (b) may be used. The terms are simply for distinguishing the components, and the essence, the sequence, and the order of the corresponding components are not limited by the terms. When it is described that a certain component is “connected to”, “coupled to” or “electrically connected to” a second component, it should be understood that the component may be directly connected or electrically connected to the second component, but a third component may be “connected” or “electrically connected” between the components.

In addition, the term ‘a passage’ used below may refer to a pipe-shaped pipe, through which a fluid may flow, and may refer to a component that may be formed of various materials and shapes, such as a soft tube or a metal pipe.

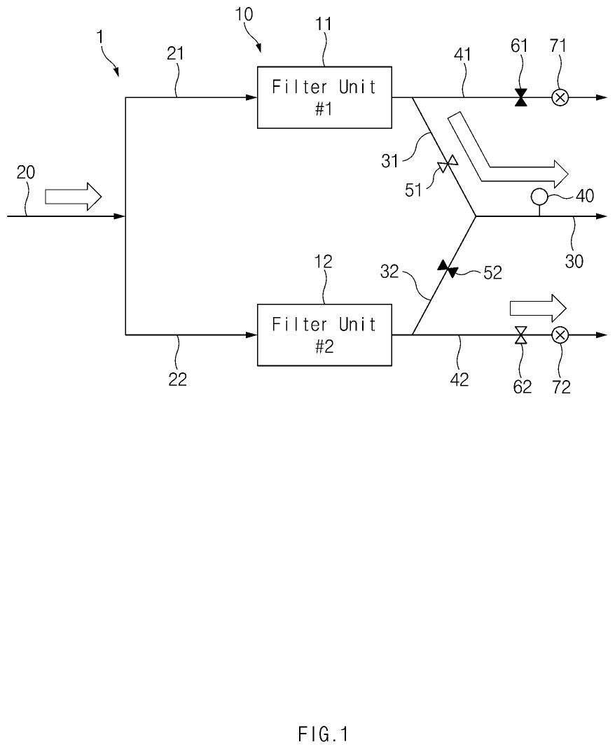

FIG. 1 is a conceptual view of a water treatment system in which a first filter unit performs a removal mode and a second filter unit performs a regeneration mode according to an embodiment.

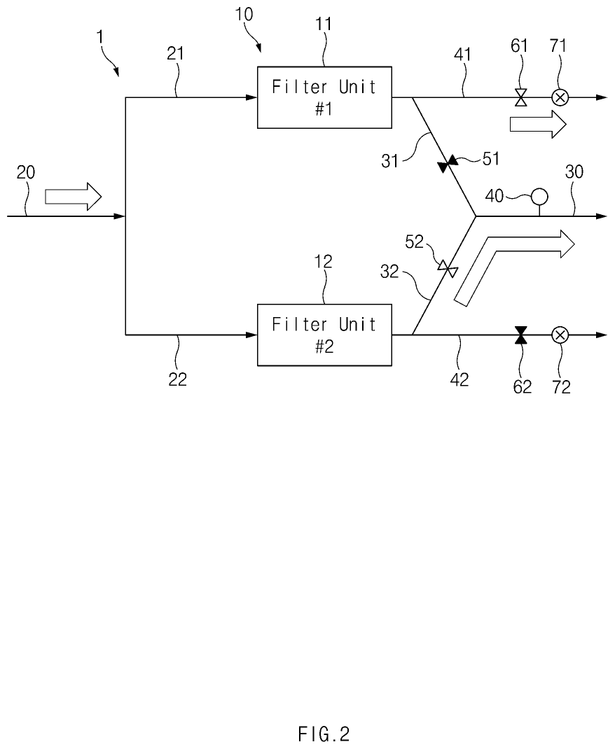

FIG. 2 is a conceptual view of a water treatment system in which the first filter unit performs a regeneration mode and the second filter unit performs a removal mode according to another embodiment.

A water treatment system 1 is a system that removes an ionic material included in supplied raw water and provides soft water to a user.

The water treatment system 1 may remove at least a portion of the ionic material included in the raw water supplied through filter units 11 and 12 based on an electrical force. The raw water, from which the ionic materials has been removed, may be provided to the user as soft water.

The water treatment system 1 may supply the ionic material collected in the filter units 11 and 12 to the raw water, and may discharge it to an outside as regeneration water.

The water treatment system 1 may include supply passages 21 and 22, the filter units 11 and 12, soft water discharge passages 31 and 32, soft water discharge valves 51 and 52, a flow amount sensor 40, regeneration water discharge passages 41 and 42, and regeneration water discharge valves 61 and 62.

### Supply Passages 21 and 22

The supply passages 21 and 22 are passages that are configured to supply the raw water to the filter units 11 and 12. A plurality of supply passages 21 and 22 may be formed and arranged in parallel. In an embodiment of the present disclosure, it is illustrated that a total of two supply passages 21 and 22 are formed and the first supply passage 21 and the second supply passage 22 are arranged in parallel, but configurations of the supply passages 21 and 22 are not limited to this.

The supply passages 21 and 22 connect a water source and the filter units 11 and 12, respectively. The first supply passage 21 may be connected to the first filter unit 11, and the second supply passage 22 may be connected to the second filter unit 12.

The supply passages 21 and 22 may be separated from a supplier passage 20 connected to the water source. For example, the first supply passage 21 separated from the supplier passage 20 may be connected to the first filter unit 11. The second supply passage 22 that is separated from the supplier passage 20 may be connected to the second filter unit 12.

The meaning of ‘connected’ here includes a case of direct connection and a case of indirect connection through other components. Accordingly, as illustrated, the water source and the supply passages 21 and 22 may be connected such that the supply passages 21 and 22 are connected to and branches off the water source passage 20 connected to the water source. Each of the supply passages 21 and 22 may be formed in a shape of a pipe body with an empty interior to deliver the raw water including at least one of the water provided from the water source and the regeneration water to the filter units 11 and 12.

The soft water discharge passages 31 and 32 and a source-of-demand passage 30 are passages that are configured to discharge the soft water. For example, the source-of-demand passage 30 is a passage that is configured to discharge the soft water discharged from the filter units 11 and 12. The soft water discharge passages 31 and 32 may include the first soft water discharge passage 31 and the second soft water discharge passage 32.

The regeneration water discharge passages 41 and 42 are passages that are configured to discharge the regeneration water. For example, the regeneration water discharge passages 41 and 42 are passages that are configured to discharge the regeneration water discharged from the filter units 11 and 12. The regeneration water discharge passages 41 and 42 may include the first regeneration water discharge passage 41 and the second regeneration water discharge passage 42.

In particular, when the filter units 11 and 12 are operated in a regeneration mode, the regeneration water that has passed through the filter units 11 and 12 may be drained and discarded to an outside through the regeneration water discharge passages 41 and 42.

Because two filter units 11 and 12 may be provided, the number of some of the soft water discharge passages 31 and 32 may be correspond to the number of filter units 11 and 12, and they may be connected to each other. For example, the first soft water discharge passage 31 may be connected to the first filter unit 11, and the second soft water discharge passage 32 may be connected to the second filter unit 12.

Because two filter units 11 and 12 may be provided, the number of some of the regeneration water discharge passages 41 and 42 may be correspond to the number of filter units 11 and 12, and they may be connected to each other. For example, the first soft water discharge passage 31 may be connected to the first filter unit 11, and the second soft water discharge passage 32 may be connected to the second filter unit 12.

In an embodiment of the present disclosure, it is illustrated that a total of two regeneration water discharge passages 41 and 42 may be provided and the first regeneration water discharge passage 41 and the second regeneration water discharge passage 42 are disposed in parallel, but configurations of the regeneration water discharge passages 41 and 42 are not limited thereto.

For the water provided from the filter units 11 and 12 to flow, the soft water discharge passages 31 and 32, the source-of-demand passage 30, and the regeneration water discharge passages 41 and 42 have shape with an empty interior.

The source-of-demand passage 30 may be formed by coupling the first soft water discharge passage 31 and the second soft water discharge passage 32. For example, the soft water that flows through the first soft water discharge passage 31 and the soft water that flows through the second soft water discharge passage 32 may be introduced into the source-of-demand passage 30. One end of the first soft water discharge passage 31 may be connected to the first filter unit 11, and an opposite end thereof may be connected to the source-of-demand passage 30. One end of the second soft water discharge passage 32 may be connected to the second filter unit 12, and an opposite end thereof may be connected to the source-of-demand passage 30.

The flow amount sensor 40, which will be described later, may be disposed in the source-of-demand passage 30.

The water that is discharged through the soft water discharge passages 31 and 32 and the regeneration water discharge passages 41 and 42 is not always discharged, and whether it is to be discharged and the discharge amount thereof may be adjusted. Accordingly, to open and close the soft water discharge passages 31 and 32 and the regeneration water discharge passages 41 and 42, discharge valves 51, 52, 61, and 62 are provided in the soft water discharge passages 31 and 32 and the regeneration water discharge passages 41 and 42.

### Discharge Valves 51, 52, 61, and 62

The discharge valves 51, 52, 61, and 62 are components that are disposed in the passages to control opening and closing of the soft water discharge passages 31 and 32 and the regeneration water discharge passages 41 and 42, respectively, and may open or close the soft water discharge passages 31 and 32 and the regeneration water discharge passages 41 and 42 as opening degrees thereof are adjusted.

When the soft water discharge passages 31 and 32 are closed by the discharge valves 51, 52, 61, and 62, the water is not delivered to the source of demand through the closed soft water discharge passages 31 and 32. When the regeneration water discharge passages 41 and 42 are closed by the discharge valves 61 and 62, the water may not be drained through the closed regeneration water discharge passages 41 and 42.

When the soft water discharge passages 31 and 32 are opened by the discharge valves 51 and 52, the water may be delivered to the source of demand through the opened soft water discharge passages 31 and 32.

When the regeneration water discharge passages 41 and 42 are opened by the discharge valves 61 and 62, the water may be drained through the opened regeneration water discharge passages 41 and 42.

At least one of the discharge valves 51, 52, 61, and 62 may be controlled by the processor to maintain an opened state during an operation of the water treatment system 1.

The discharge valves 51 and 52 that maintain the opened state may be the soft water discharge valves 51 and 52 that are disposed in the source-of-demand passage 30 connected to the filter units 11 and 12 that performing the removal mode. Furthermore, the discharge valves 61 and 62 that maintain the opened state are the regeneration water discharge valves 61 and 62 that are disposed in the regeneration water discharge passages 41 and 42 connected to the filter units 11 and 12 that perform the regeneration mode. Accordingly, even while one of the filter units 11 and 12 performs the regeneration mode, the soft water discharged from the filter units 11 and 12 that perform the removal mode may be delivered to the supplier.

As illustrated, the source-of-demand passage and the soft water discharge passages 31 and 32 may be connected in a scheme, in which the soft water discharge passages 31 and 32 are connected to and combined with the source-of-demand passage 30 connected to the source of demand. The flow amount sensor 40, which will be described later, may be disposed in the source-of-demand passage 30.

The soft water discharge valves 51 and 52 may include the first soft water discharge valve 51 and the second soft water discharge valve 52. The first soft water discharge valve 51 may be disposed in the first soft water discharge passage 31, and the second soft water discharge valve 52 may be disposed in the second soft water discharge passage 32. The discharge amount of soft water that flows through the first soft water discharge passage 31 may be adjusted by the first soft water discharge valve 51. The discharge amount of the soft water that flows through the second soft water discharge passage 32 may be adjusted by the second soft water discharge valve 52. For example, the processor may perform a control to open or close the first soft water discharge valve 51 or the second soft water discharge valve 52 to adjust the discharge amount of soft water discharged from the filter units 11 and 12.

The regeneration water discharge valves 61 and 62 may include the first regeneration water discharge valve 61 and the second regeneration water discharge valve 62. The first regeneration water discharge valve 61 may be disposed in the first regeneration water discharge passage 41, and the second regeneration water discharge valve 62 may be disposed in the second regeneration water discharge passage 42. The discharge amount of the regeneration water that flows through the first regeneration water discharge passage 41 may be adjusted by the first regeneration water discharge valve 61. The discharge amount of the regeneration water that flows through the second regeneration water discharge passage 42 may be adjusted by the second regeneration water discharge valve 62.

The processor may perform a control to open or close the first regeneration water discharge valve 61 or the second regeneration water discharge valve 62 to adjust the discharge amount of the regeneration water discharged from the filter units 11 and 12. For example, when the processor determines that regenerative capacities of the first filter unit 11 or the second filter unit 12, which perform a regeneration operation, is exceeded, the processor may open the first regeneration water discharge valve 61 or the second regeneration water discharge valve 62 to discharge the regeneration water. For example, when the processor determines that the regenerative capacity of the first filter unit 11 or the second filter unit 12, which performs a regeneration operation, is sufficient, the processor may close the first regeneration water discharge valve 61 or the second regeneration water discharge valve 62 and may not discharge the regeneration water.

### Flow Amount Sensor 40

The flow amount sensor 40 is a component that acquires the flow amount of the water that is delivered to the source of demand, that is, the flow amount of the water used by the user. The flow amount sensor 40 is configured to acquire the flow amount of the soft water discharged by the first filter unit 11 or the second filter unit 12 that performs the removal mode. Accordingly, the flow amount sensor 40 may be disposed in the source-of-demand passage 30 to acquire the flow amount of the water that passes through the source-of-demand passage 30. The flow amount sensor 40 may acquire the flow amount of the water that is delivered to the source of demand by using a Kalman vortex method, a method using the Doppler effect, and the like, but the method of acquiring the flow amount is not limited to this.

The flow amount sensor 40 is connected to the processor, and delivers the acquired flow amount to the processor. The processor may acquire a data value of the total flow amount of the soft water that is discharged by the filter units 11 and 12 while the filter units 11 and 12 perform the removal mode through the received flow amount.

The processor may adjust whether to open or close the valves according to the acquired total flow amount. Furthermore, the processor may control an operation of a pump based on the received flow amount, and may determine operation states of the filter units 11 and 12.

### Processor

A processor is a component that includes elements capable of logical operations that perform control commands, and may include a central processing unit (CPU). The processor may be connected to components, such as the filter units 11 and 12 and the discharge valves 51, 52, 61, and 62, may deliver signals according to control commands to the components, and may be connected to various sensors or acquisition parts to receive the acquired information in a form of a signal. Accordingly, in an embodiment of the present disclosure, the processor may be electrically connected to the valves, the filter units 11 and 12, the flow amount sensor 40, and the pump included in the water treatment system 1. Because the processor may be electrically connected to the components, they may be connected to each other with a conductive wire or further include a communication module capable of wireless communication to communicate each other.

The water treatment system 1 may further include a storage medium, and thus control commands performed by the processor may be stored in the storage medium to be utilized. The storage medium may be a device, such as a hard disk drive (HDD), a solid state drive (SSD), a server, a volatile medium, or a non-volatile medium, but the kind thereof is not limited thereto. In addition, data that are necessary for the processor to perform tasks may be stored in the storage medium.

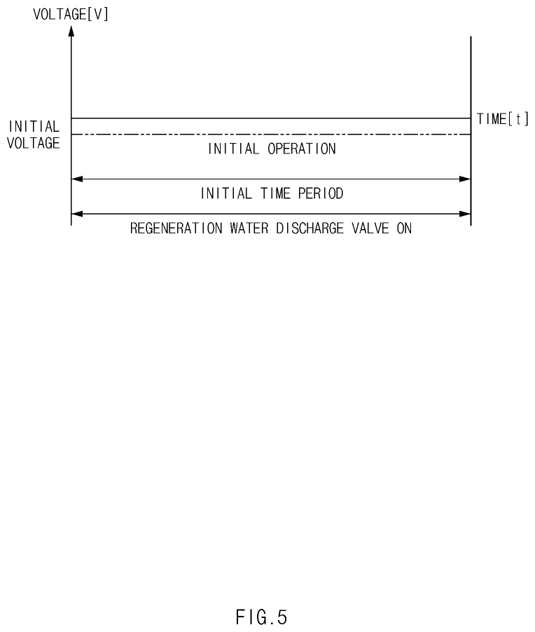

The scheme of, by the processor, controlling the water treatment system 1 will be described with reference to FIGS. 5, 6, and 7.

### Filter Units 11 and 12

The filter units 11 and 12 are components that generate soft water by removing the ionic material in the raw water.

The filter units 11 and 12 are provided in the supply passages 21 and 22, respectively, and may remove at least a portion of the ionic material included in the supplied raw water by an electrical force to discharge the soft water including less ionic material than the raw water. This operation state may be referred to as the removal mode.

The filter units 11 and 12 may discharge the ionic material collected during the removal mode together with the supplied raw water, to discharge the regeneration water including more ionic material than the raw water. This operation state may be referred to as the regeneration mode.

The filter units 11 and 12 may selectively perform any one of the removal mode or the regeneration mode. For example, the filter units 11 and 12 may alternately perform any one of the removal mode and the regeneration mode at a constant cycle. A plurality of filter units 11 and 12 may be provided and it has been described in an embodiment of the present disclosure that two filter units 11 and 12 of the first and second filter units 11 and 12 are disposed, but the configuration thereof is not limited thereto.

The filter units 11 and 12 may remove the ionic material by using an electric deionization method. More specifically, one of the methods for removing ionic materials is the electric deionization method. When a direct current voltage is applied to charged particles in an electrolyte, positively charged particles move to a negative electrode, and negatively charged particles move to a positive electrode. This is called electrophoresis. The electric deionization method refers to a method of removing ions (ionic materials) in water by selectively adsorbing or moving them through electrodes or ion exchange membranes based on the principle of an electrical force (electrophoresis).

The electric deionization method includes electrodialysis (ED), electro deionization (EDI), continuous electro deionization (CEDI), and capacitive deionization (CDI). The ED type filter units 11 and 12 includes electrodes and an ion exchange membrane. Furthermore, the EDI type filter units 11 and 12 includes electrodes, an ion exchange membrane, and an ion exchange resin. On the other hand, the CDI type filter units 11 and 12 do not include either an ion exchange membrane or an ion exchange resin, or do not include an ion exchange resin.

The filter units 11 and 12 according to an embodiment of the present disclosure may remove the ionic material by using, among the electric deionization methods, a capacitive deionization (CDI) method. The CDI method refers to a method of removing ions by using the principle of adsorbing and desorbing ions (or ionic materials) to and from a surface of an electrode with an electrical force.

### Pressure Reducing Rings 71 and 72

The water treatment system 1 may further include the pressure reducing rings 71 and 72.

The pressure reducing rings 71 and 72 may adjust a flow amount of the regeneration water. For example, the pressure reducing rings 71 and 72 may be disposed in the regeneration water discharge passages 41 and 42 to adjust the flow amount of the regeneration water discharged through the regeneration water discharge passages 41 and 42.

The configuration for adjusting the flow amount of the regeneration water has been described by using the pressure reducing rings 71 and 72 as an example, but the present disclosure is not limited thereto. For example, a flow amount adjusting valve may adjust the flow amount of regeneration water.

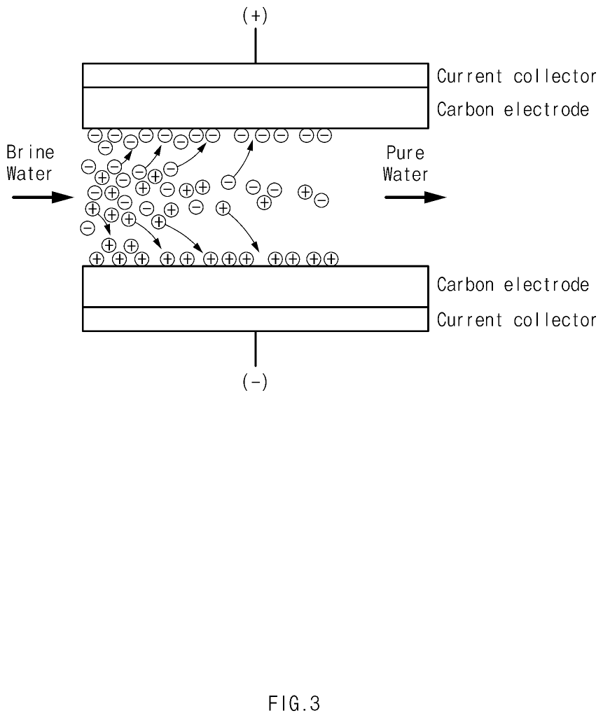

FIG. 3 is a conceptual view illustrating the principle of removing the ionic material in the CDI method.

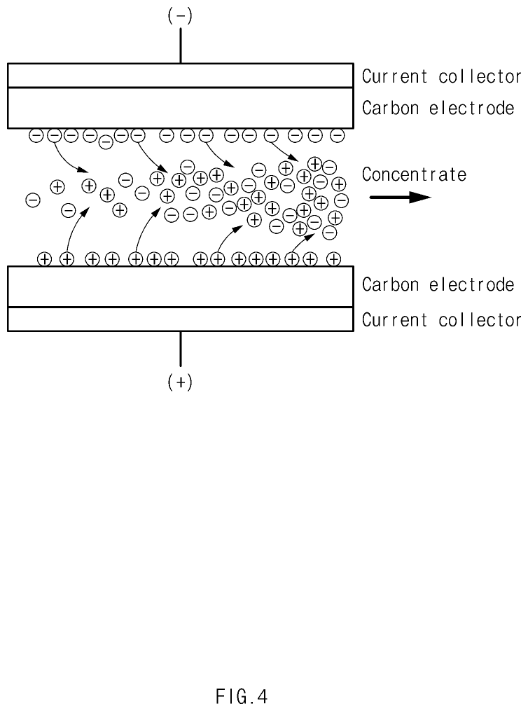

FIG. 4 is a conceptual view illustrating a principle of electrode regeneration in a CDI method.

Referring further to FIGS. 3 and 4, the removal mode and the regeneration mode of the CDI method will be described.

As illustrated in FIG. 3, when the water including ions passes between the electrodes while a voltage is applied to the electrodes, negative ions move to the positive electrode and positive ions move to the negative electrode. That is, adsorption occurs. The ions may be removed from the water through the adsorption. In this way, a mode, in which the filter units 11 and 12 remove the ions (ionic material) from the water that passes through the filter units 11 and 12 through the electrodes is referred to as the removal mode.

However, an adsorption capacity of the electrode is restrictive. Accordingly, when the adsorption continues, the electrode reaches a state, in which it may no longer adsorb the ions. To prevent this, it is necessary to regenerate the electrode by desorbing the ions adsorbed to the electrode. To achieve this, as illustrated in FIG. 4, a voltage opposite to that in the removal mode may be applied to the electrode, or no voltage may be applied. In this way, the mode, in which the filter units 11 and 12 regenerate the electrodes, is referred to as the regeneration mode. The regeneration mode may be performed before or after the removal mode.

Accordingly, for this operation, the filter units 11 and 12 may include electrodes. The filter units 11 and 12 may selectively perform any one of the removal mode of removing the ionic material by using the electric deionization method through the electrodes, or the regeneration mode of regenerating the electrodes. Accordingly, when the raw water is supplied to the filter units 11 and 12, at least a portion of the ionic material in the raw water is removed to generate the soft water and is discharged from the filter units 11 and 12 in the removal mode, and the filter units 11 and 12 may discharge the water with an increased content of the ionic material by providing the ionic material in the electrodes to the raw water in the regeneration mode.

As described above, the filter units 11 and 12 may be connected to the supply passages 21 and 22, the soft water discharge passages 31 and 32, and the regeneration water discharge passages 41 and 42, respectively, to receive and discharge the water through the supply passages 21 and 22. The raw water including at least one of the water delivered from the water source and the regeneration water may be provided to the filter units 11 and 12, and the soft water may be generated and discharged by removing the ionic material from the provided raw water and discharging the ionic material.

FIG. 5 is a voltage and time graph depicting an initial operation of the regeneration mode when an electric voltage is first supplied to the filter unit that performs the regeneration mode.

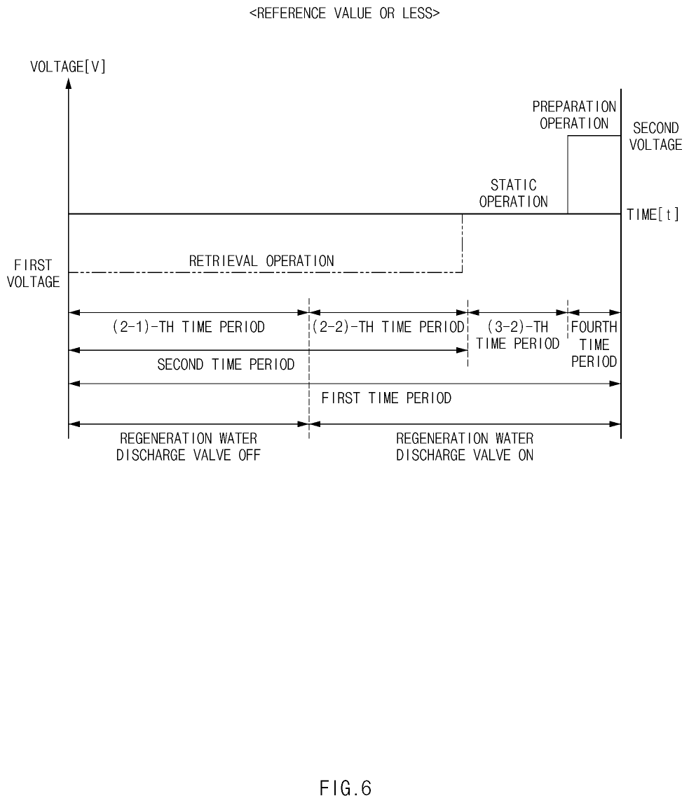

FIG. 6 is a voltage and time graph of the second filter unit that performs the regeneration mode when the total amount of the soft water that is discharged in the previous removal mode is a reference value or less.

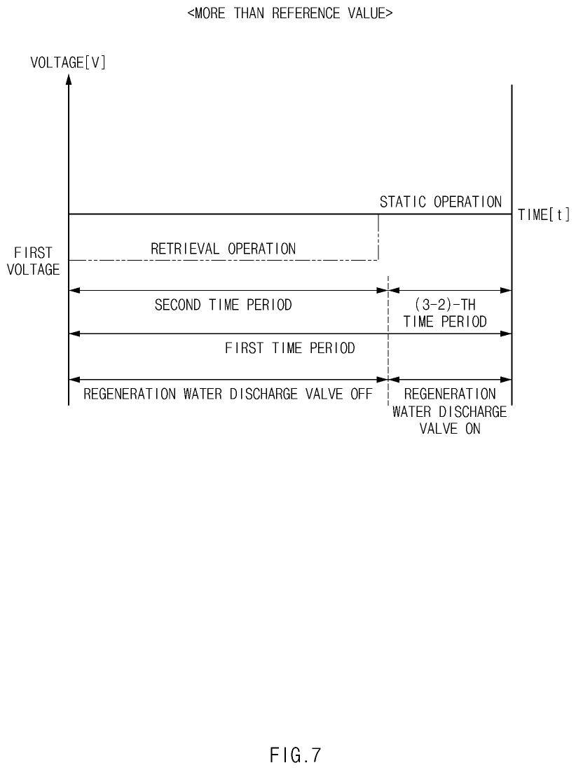

FIG. 7 is a voltage and time graph of the second filter unit that performs the regeneration mode when the flow amount of soft water discharged in the previous removal mode is more than the reference value.

The x-axis of the graphs in FIGS. 5 to 7 defines time values, and the y-axis defines voltage values. The unit of the time values on the x-axis is see [s], and the unit of the voltage values on the y-axis is volt [V].

Hereinafter, a description will be made with an assumption that the first filter unit 11 performs the removal mode and the second filter unit 12 performs the regeneration mode.

However, this is for convenience of description, and the first filter unit 11 and the second filter unit 12 may alternately perform the removal mode and the regeneration mode, respectively. For example, the first filter unit 11 and the second filter unit 12 may alternately perform one of the removal mode and the regeneration mode at every specific time period. For example, when the second filter unit 12 performs the removal mode during a first time period, the first filter unit 11 may perform the regeneration mode during the first time period. Then, the water flow and the operating state of the valve also may be changed correspondingly and thus, the water treatment system 1 may be operated. For example, the first time period may range from about 80 seconds to about 100 seconds. For example, the first time period may be 90 seconds, but the present disclosure is not limited thereto. For example, the first time period may include a range from about 110 seconds to about 130 seconds.

The first time period refers to a period, in which each of the filter units 11 and 12, which has performed an initial operation that will be described later, performs the removal mode and the regeneration mode.

The regeneration mode may include the initial operation, the retrieval operation, the static operation, and the preparation operation.

The initial operation is an operation of first supplying an electric voltage to the filter units 11 and 12 that perform the regeneration mode.

The retrieval operation is an operation of generating the regeneration water by applying an opposite electric voltage to that of the removal mode to the filter units 11 and 12. By the retrieval operation, the ionic material adsorbed to the filter units 11 and 12 is supplied to the raw water, and thus, the ionic material collected in the filter units 11 and 12 may be removed. The regeneration water may be generated by supplying the ionic material to the raw water.

In the retrieval operation, the processor may control the second filter unit 12 to generate the regeneration water by applying a first electric voltage that is opposite to the second electric voltage applied to the first filter unit 11, to the second filter unit 12.

The first electric voltage may have a negative (−) value, and the second electric voltage may have a positive (+) value, but the present disclosure is not limited thereto. For example, the first electric voltage may include about 0 V.

An absolute value of a first voltage value of the first electric voltage and an absolute value of a second voltage value of the second electric voltage may be different. For example, the first voltage may have a value within about 0 V to about −100 V, and the second voltage may have a value of about +200 V, but the specific voltage value is not limited thereto.

The static operation is an operation, in which no electric voltage is applied to the filter units 11 and 12. By the static operation, the ionic material supplied to the raw water may be prevented from being adsorbed to the filter units 11 and 12 again. For example, by preventing the ionic material of the regeneration water from being adsorbed to the filter units 11 and 12 again, an adsorption capacity of the filter units 11 and 12 that perform the removal mode after the regeneration mode may be increased.

The processor may perform a control such that the electric voltage is not applied to the second filter unit 12 that performs the regeneration mode. For example, the voltage value applied to the second filter unit 12 may be about 0 V, but the voltage value is not limited thereto.

The preparation operation is an operation that is performed before switching to the removal mode. The preparation operation is an operation of minimizing the total dissolved solids (TDS) of the regeneration water that remains in the filter units 11 and 12 and the TDS of the filter before the switching to the removal mode. By minimizing the TDS of the regeneration water and the TDS of the filter, the regeneration water with a high TDS and the raw water with a high TDS may be prevented from being supplied to the user as soft water at the beginning of the operation in the removal mode.

The processor may apply a second electric voltage that is different from the first electric voltage to the filter units 11 and 12 before the filter units 11 and 12 are switched from the static operation of the regeneration mode to the removal mode. The preparation operation may be omitted in some cases.

Referring to FIG. 5, the initial operation is an operation when the electric voltage is first supplied to the filter units 11 and 12 that perform the regeneration mode. The regeneration mode in the initial operation may not include the retrieval operation, the static operation, and the preparation operation.

In the initial operation of the regeneration mode, the processor may apply an initial electric voltage to the second filter unit 12 during an initial time period. For example, the initial voltage value may range from about 0 V to about 5 V [volt], but the present disclosure is not limited thereto. For example, the initial time period may be described by using 120 seconds as an example, but the time period is not limited thereto.

When the second filter unit 12 that performs the regeneration mode performs the initial operation during the initial time period, the first filter unit 11 may perform the removal mode during the initial time period. For example, when the initial time period is 120 seconds, the second filter unit 12 may perform the regeneration mode for 120 seconds, and the first filter unit 11 may perform the removal mode for 120 seconds.

When the processor applies the first electric voltage to the second filter unit 12, the processor may perform a control such that the second regeneration water discharge valve 62 is opened for the initial time period. For example, the processor may perform a control such that the second regeneration water discharge valve 62 is opened whereby the regeneration water discharged through the second filter unit 12 may be discharged to an outside through the second regeneration water discharge passage 42.

At an initial operation, at which the filter units 11 and 12 are operated in the regeneration mode, a large amount of ionic material included in the filter units 11 and 12 is discharged together with water whereby the total dissolved solids (TDS) of the regeneration water r is excessively high and thus the regeneration water is retrieved and a quality of the soft water may be degraded. Accordingly, the regeneration water that is initially generated needs to be drained instead of being retrieved.

The initial time period may be longer than the first time period for performing the regeneration mode and the removal mode. For example, the initial time period may include about 110 seconds to about 130 seconds, and the first time period may include about 80 seconds to about 100 seconds. For example, the initial time period may be about 120 seconds, and the first time period may be about 90 seconds.

The flow amount sensor 40 may measure the flow amount of the soft water discharged through the soft water discharge passages 31 and 32. For example, the flow amount sensor 40 may be disposed in the source-of-demand passage 30 to measure the flow amount of the soft water that flows in the source-of-demand passage 30. The processor may acquire the data value of the total amount of the soft water discharged by any one filter unit 11 or 12 that performs the removal mode through the flow amount sensor 40. As an example, the processor may distinguish whether the total flow amount of the soft water discharged in the removal mode shortly before the second filter unit 12 performs the regeneration mode is the reference value or less or more than the reference value.

For example, the second filter unit 12 may perform the removal mode shortly before performing the regeneration mode. When performing the removal mode, the processor may acquire the total amount of the soft water discharged while performing the removal mode, by using the flow amount sensor 40. The filter units 11 and 12 that perform the removal mode may decrease a removal operation amount, which is a performance of the filter units 11 and 12, depending on the total amount of the discharged soft water. The processor may compare the reduced removal operation amount of the filter units 11 and 12 with a previously stored reference value. That is, the processor may compare the total amount of the discharged soft water with the previously stored reference value.

The reference value may be an experimental value that is acquired by testing a filtering performance of the filter units 11 and 12 in advance. The reference value is a value that is stored in the process in advance and may vary depending on a filtering performance of the filter units 11 and 12.

The processor may compare the acquired total amount of the soft water and the reference value stored in advance to distinguish when the total flow amount of the measured soft water is the reference value or less and when it is more than the reference value, and the operations of the regeneration mode immediately after the performance of the filter units 11 and 12 and whether the regeneration water discharge valve is opened and closed may be adjusted differently.

By comparing the total discharge amount of the soft water, which is acquired by the processor, and the reference value, the operations of the filter units 11 and 12 that perform the regeneration mode may be changed. When the total amount of the soft water discharged in the removal mode shortly before the performance of the regeneration mode is the reference value or less, the required operation amount for the regeneration of the filter units 11 and 12 may be increased, and when the flow amount is more than the reference value, the required operation amount for the regeneration of the filter units 11 and 12 may be decreased.

The required operation amount for the regeneration may mean a capability of the filter units 11 and 12, which is required to remove the adsorbed ionic material.

When the total flow amount of the soft water, which is acquired in the previous removal mode is the reference value or less, the TDS of the supplied raw water is relatively high whereby the required operation amount for the regeneration of the filter units 11 and 12 may increase. When the total flow amount of the soft water, which is acquired in the previous removal mode, is more than the reference value, the required operation amount for the regeneration of the filter units 11 and 12 may decrease because the TDS of the supplied raw water is relatively low.

For example, when the total flow amount of the soft water, which is acquired in the previous removal mode, is the reference value or less, the required capacity required for the regeneration of the filter units may be more than 50% of a maximum capacity. For example, when the total flow amount of the soft water, which is acquired in the previous removal mode, is more than the reference value, the required operation amount required for the regeneration of the filter units may be 50% of the maximum capacity or less.

When the TDS of the supplied raw water is relatively high, a relatively small amount of soft water may be discharged from the filter units 11 and 12 that perform the removal mode. As a relatively small amount of soft water is discharged, the processor may determine that the total flow amount of the soft water, which is acquired in the previous removal mode through the flow amount sensor 40, the reference value or less.

When the TDS of the raw water supplied in the removal mode shortly before the regeneration mode is relatively high and the total flow amount of the soft water acquired in the removal mode shortly before the regeneration mode is the reference value or less, the filter units 11 and 12 that perform the removal mode may be required to remove a relatively large amount of ionic material. As the filter units 11 and 12 remove a relatively large amount of ionic material, the ionic material adsorbed to the filter units 11 and 12 also may increase. As the adsorbed ionic material increases, the required operation for the regeneration of the filter units 11 and 12 that perform the regeneration mode may increase.

When the required operation amount is more than an actual operation amount of the filter units 11 and 12, the filter units 11 and 12 may discharge the regeneration water and may remove the ionic material included in the filter units 11 and 12 by using newly supplied raw water.

Accordingly, when the total flow amount of the soft water acquired in the previous removal mode is the reference value or less, additional work for draining the regeneration water may be required as the required operation amount for the regeneration of the filter units 11 and 12 increases,

When the TDS of the raw water supplied in the removal mode shortly before the performance of the regeneration mode is relatively low, the filter units 11 and 12 that perform the removal mode are required to remove a relatively small amount of ionic material from the raw water. As the filter units 11 and 12 remove a relatively small amount of ionic material, the ionic material adsorbed to the filter units 11 and 12 also may decrease.

As the ionic material adsorbed to the filter units 11 and 12 decreases, the required operation amount for the regeneration of the filter units 11 and 12 that perform the regeneration mode may decrease. When the required operating amount is the actual operating amount of the filter units 11 and 12 or less, the filter units 11 and 12 may remove the ionic material without discharging the regeneration water.

Accordingly, when the total flow amount of the soft water acquired in the previous removal mode is more than the reference value, the operation amount required for the regeneration of the filter units 11 and 12 decreases whereby no additional work is required to drain the regeneration water.

As no additional work is required to drain the regeneration water based on the flow amount of the soft water, an amount of discarded water may be reduced.

As described above, the retrieval operation may be an operation of removing the ionic material included in the second filter unit 12. The retrieval operation may be performed during the second time period. The second time period may be shorter than the first time period. For example, the retrieval operation that is performed during the second time period may be a partial operation of a progress mode during the first time period.

Referring to FIG. 6, when the total flow amount of the soft water acquired by the processor in the previous removal mode is the reference value or less, the processor may perform a control to open the closed second regeneration water discharge valve 62 after lapse of a specific period of time.

Referring to FIG. 6, when it is determined that the total flow amount of the soft water acquired in the previous removal mode is the reference value or less, the processor of the water treatment system 1 that performs the retrieval operation may perform a control to close the second regeneration water discharge valve 62 for a specific time period, and may perform a control to open the second regeneration water discharge valve 62 after lapse of the specific time period. For example, when it is determined that the total flow amount of the soft water acquired in the previous removal mode is the reference value or less, the processor of the water treatment system 1 that performs the retrieval operation may perform a control to close the second regeneration water discharge valve 62 during the (2-1)-th time period of the second time period, and may perform a control to open the second regeneration water discharge valve 62 during the (2-2)-th time period after lapse of the (2-1)-th time period. In this case, when it is determined that the total flow amount of the soft water acquired in the previous removal mode is the reference value or less, the second regeneration water discharge valve 62 may be controlled by the processor to be opened and closed once for each.

The processor may perform a control to close the second regeneration water discharge valve 62 to interrupt the flow of the regeneration water during the (2-1)-th time period of the second time period. As the processor closes the second regeneration water discharge valve 62, the ionic material included in the second filter unit 12 may be removed.

When the required operation amount for the regeneration of the second filter unit 12 is more than the operation amount of the second filter unit 12 while the second regeneration water discharge valve 62 is closed, the ionic material may be supersaturated in the regeneration water. As the ionic material becomes supersaturated, a process of discharging the regeneration water and a process of receiving new raw water may be required.

The (2-1)-th time period may include a time period for removing the ionic material included in the second filter units 11 and 12 within an actual operating amount of the second filter unit 12. For example, the (2-1)-th time period may include a time period until the ionic material is supersaturated in the supplied raw water.

The processor may perform a control to open the second regeneration water discharge valve 62 to allow the flow of the regeneration water during the (2-2)-th time period of the second time period. As the processor opens the second regeneration water discharge valve 62, the regeneration water generated from the second filter unit 12 may be discharged to an outside.

The second time period may be the sum of the (2-1)-th time period and the (2-2)-th time period. That is, the (2-2)-th time period may be a time period excluding the (2-1)-th time period in the second time period. The (2-2)-th time period may be shorter than the (2-1)-th time period, but the present disclosure is not limited thereto. For example, when the second time period, in which the retrieval operation is performed, is 70 seconds, the (2-1)-th time period, in which the second regeneration water discharge valve 62 is closed, may be in progress for 50 seconds, the (2-2)-th time period, in which the second regeneration water discharge valve 62 is opened, may be in progress for 20 seconds, but this is not specifically limited.

The processor may perform a control such that the second filter unit 12 further performs the static operation after the retrieval operation.

The second regeneration water discharge valve 62 may be opened even while the static operation is performed. Because the static operation is an operation for preventing the ionic material from being adsorbed to the second filter unit 12 again, the raw water supplied to the second filter unit 12 may be required to be discharged through the second regeneration water discharge valve 62.

The static operation may be in progress during the (3-1)-th time period. The (3-1)-th time period may be shorter than the second time period. For example, when the second time period is 70 seconds, the (3-1)-th time period may be 15 seconds.

The processor may perform a control such that the second filter unit 12 further performs a preparation operation after the static operation.

As described above, the preparation operation may be a preliminary operation that is performed before the switching from static operation to removal mode during the regeneration mode. The preparation operation may be in progress for a fourth time period. The fourth time period may be shorter than the third time period. For example, when the (3-1)-th time period is 15 seconds, the fourth time period may be in progress for 5 seconds, but the present disclosure is not limited to this.

For example, in the preparation operation before the switching to the regeneration mode, the processor may apply an electric voltage that is different from the electric voltage applied in the retrieval operation to the second filter unit 12. As a different electric voltage is applied to the second filter unit 12, at least a portion of the ionic material included in the supplied raw water may be removed based on an electrical force.

Even while the preparation operation is in progress, the second regeneration water discharge valve 62 may be opened. As the preliminary operation of the removal mode, to minimize the ionicity of the raw water that remains in the second filter unit 12, the processor may discharge the raw water that passes through the second filter unit 12, through the second regeneration water discharge valve 62.

As the regeneration water is discharged in the preparation operation, the TDS of the regeneration water that remains in the second filter unit 12 may decrease. As the TDS decreases, the second filter unit 12, which is switched to the removal mode, removes the ionic material before the switching to the removal mode whereby the regeneration water including the ionic material may be prevented from being discharged as the soft water through the soft water discharge passage.

Referring to FIG. 7, when the total flow amount of the soft water acquired by the processor in the previous removal mode is more than the reference value, the processor may perform a control such that the second regeneration water discharge valve 62 is closed for a longer time than when the flow amount of soft water is the reference value or less.

When the total flow amount of the soft water acquired by the processor in the previous removal mode is more than the reference value, the processor may control the second regeneration water discharge valve 62 to interrupt the flow of regeneration water discharged through the second regeneration water discharge passage 42 for a specific time period. For example, the processor may perform a control such that the second regeneration water discharge valve 62 is closed during the second time period to interrupt the flow of the regeneration water discharged through the second regeneration water discharge passage 42 in the retrieval operation of the regeneration mode. In this case, when the total flow amount of the soft water acquired in the previous removal mode is more than the reference value, the second regeneration water discharge valve 62 may be controlled by the processor to be opened and closed once each.

For example, when the total flow amount of the soft water acquired in the previous removal mode is more than the reference value, the processor may perform a control to close the second regeneration water discharge valve 62 during the second time period, and may perform a control to open the second regeneration water discharge valve 62 during the (3-2)-th time period after lapse of the second time period.

Unlike the water treatment system of FIG. 6, which opens the second regeneration water discharge valve 62 after elapse of the (2-1)-th time period of the second time period, the water treatment system 1 of FIG. 7 may close the second regeneration water discharge valve 62 before the lapse of the second time period. For example, when the processor of the soft water system 1 of FIG. 7 determines that the total flow amount of the soft water acquired in the previous removal mode is more than the reference value, it may perform a control to close the second regeneration water discharge valve 62 for the second time period.

When the amount of soft water is more than the reference value, less ionic material than when the amount of the soft water is less than the reference value may be included in the second filter unit 12. As less ionic material is included, the ionic material may not be supersaturated in the second filter unit 12 during the retrieval operation. As it is not supersaturated, the second filter unit 12 may perform the regeneration mode without discharging the regeneration water.

By comparing the total flow amount of the soft water acquired in the previous removal mode and the reference value, and the water treatment system 1 may minimize the discarded water by adjusting the opening and closing of the second regeneration water discharge valve 62 depending on whether the acquired total flow amount of soft water is more than the reference value. For example, the water treatment system 1 that adjusts the opening and closing of the regeneration water discharge valves 61 and 62 depending on whether the reference value is exceeded drains a smaller amount of regeneration water than the water treatment system that discharges the regeneration water after lapse of a specific time period regardless of whether the reference value is exceeded. In addition, by the opening and closing operation of the second regeneration water discharge valve 62, foreign substances formed in the second regeneration water discharge valve 62 may be removed.

By adjusting the amount of discarded water, the water treatment system 1 may protect the environment. The water treatment system 1 may provide an environment-friendly water treatment system. Furthermore, as operation costs of the water treatment system 1 decreases, an efficiency of the water treatment system 1 may increase.

The processor may perform a control to perform a static operation during the (3-2)-th time period after the retrieval operation. As the static operation is performed, the ionic material may be prevented from being adsorbed to the second filter unit 12 again. As the ionic material is prevented from being adsorbed to the second filter unit 12 again, an adsorption capacity of the second filter unit 12 that performs the removal mode may increase.

The second regeneration water discharge valve 62 may be opened even while the static operation is performed. Because the static operation is an operation for preventing the ionic material from being adsorbed to the second filter unit 12 again, the raw water supplied to the second filter unit 12 may be required to be discharged through the second regeneration water discharge valve 62.

The (3-2)-th time period may be shorter than the second time period. For example, when the second time period is 70 seconds, the (3-2)-th time period may be 20 seconds. The (3-2) -th time period may be a time period that is different from the (3-1)-th time period, but the present disclosure is not limited thereto.

The processor may perform a control such that the second filter unit 12 further performs the preparation operation after the static operation.

As described above, the preparation operation may be a preliminary operation that is performed before switching from the static operation to the removal mode during regeneration mode. The preparation operation may be in progress for the fourth time period. The fourth time period may be shorter than the (3-2)-th time period. For example, when the (3-2)-th time period is 15 seconds, the fourth time period may 5 seconds, but the present disclosure is not limited thereto.

For example, in the preparation operation before the switching to the regeneration mode, the processor may apply an electric voltage that is different from the electric voltage applied in the retrieval operation to the second filter unit 12. By applying a different electric voltage to the second filter unit 12, at least portion of the ionic material included in the supplied raw water may be removed based on electrical force.

Even while the preparation operation is in progress, the second regeneration water discharge valve 62 may be opened. As a preliminary operation of the removal mode, to minimize the ionicity of the raw water that remains in the second filter unit 12, the processor may discharge the raw water that passes through the second filter unit 12, through the second regeneration water discharge valve 62.

As the regeneration water is discharged during the preparation operation, the TDS of the regeneration water that remains in the second filter unit 12 may decrease. As the TDS decreases, the second filter unit 12 that is switched to the removal mode may remove the ionic material before the switching to the removal mode whereby the regeneration water including the ionic material may be prevented from being discharged as the soft water.

According to the present disclosure, the water treatment system with an increased efficiency may be provided.

According to the present disclosure, the environment-friendly water treatment system may be provided.

The above description is a simple exemplary description of the technical spirits of the present disclosure, and an ordinary person in the art, to which the present disclosure pertains, may make various corrections and modifications without departing from the essential characteristics of the present disclosure. Therefore, the embodiments disclosed in the present disclosure are not for limiting the technical spirits of the present disclosure but for describing them, and the scope of the technical spirits of the present disclosure is not limited by the embodiments. The protection scope of the present disclosure should be construed by the following claims, and all the technical spirits in the equivalent range should be construed as being included in the scope of the present disclosure.

What is claimed is:

1. A water treatment system comprising:
a first filter unit and a second filter unit configured to selectively perform any one of a removal mode of removing at least a portion of an ionic material included in supplied raw water based on an electrical force to discharge soft water including less ionic material than the raw water, and a regeneration mode of discharging the ionic material collected in the removal mode together with the supplied raw water to discharge regeneration water including the ionic material being more than the raw water;
a first soft water discharge passage and a second soft water discharge passage configured to discharge the soft water from the first filter unit and the second filter unit, and a source-of-demand passage, in which the first soft water discharge passage and the second soft water discharge passage are integrated;
a first regeneration water discharge passage and a second regeneration water discharge passage configured to discharge the regeneration water from the first filter unit and the second filter unit;
a first regeneration valve and a second regeneration valve disposed in the first regeneration water discharge passage and the second regeneration water discharge passage, and configured to adjust a discharge amount of the regeneration water;
a flow amount sensor disposed in the source-of-demand passage to measure a flow amount of the soft water discharged from the first filter unit or the second filter unit; and
a processor electrically connected to the first filter unit, the second filter unit, the first regeneration valve, the second regeneration valve, and the flow amount sensor,
wherein when it is assumed that the first filter unit performs the removal mode and the second filter unit performs the regeneration mode for a first time period,
the processor is configured to:
perform a control to close the second regeneration valve to interrupt flow of the regeneration water discharged through the second regeneration water discharge passage for a second time period being shorter than the first time period when a total amount of the soft water discharged in the removal mode shortly before the regeneration mode is performed is more than a reference value; and
perform a control to close the second regeneration valve to interrupt the flow of the regeneration water discharged through the second regeneration water discharge passage for a (2-1)-th time period of the second time period and to open the second regeneration valve to allow the flow of the regeneration water for a (2-2)-th time period of the second time period when the total amount of the soft water discharged in the removal mode shortly before the regeneration mode is performed is less than the reference value.

2. The water treatment system of claim 1, wherein the regeneration mode includes:
a retrieval operation configured to apply an electric voltage to one of the first filter unit and the second filter unit, which performs the regeneration mode, to supply the ionic material to the raw water; and
a static operation of not applying the electric voltage to the one of the first filter unit and the second filter unit, which performs the regeneration mode, after the retrieval operation, and
wherein the retrieval operation is performed for the second time period.

3. The water treatment system of claim 2, wherein the processor performs a control such that the second filter unit performs the static operation for a (3-1)-th time period being shorter than the second time period when the total amount of the soft water discharged in the removal mode shortly before the regeneration mode is performed is the reference value or less.

4. The water treatment system of claim 3, further comprising:
a preparation operation of applying an electric voltage opposite to the electric voltage applied in the retrieval operation to the first filter unit and the second filter unit to remove at least a portion of the ionic material included in the raw water based on the electrical force, before switching to the removal mode after the static operation.

5. The water treatment system of claim 4, wherein the processor performs a control such that the second filter unit performs the preparation operation for a fourth time period being shorter than the (3-1)-th time period.

6. The water treatment system of claim 2, wherein the processor performs a control such that the second filter unit performs the static operation for a (3-2)-th time period being shorter than the second time period when the total amount of the soft water discharged in the removal mode shortly before the regeneration mode is performed is more than the reference value.

7. The water treatment system of claim 6, wherein the regeneration mode further includes:
a preparation operation of applying an electric voltage opposite to the electric voltage applied in the retrieval operation to the first filter unit and the second filter unit to remove at least a portion of the ionic material included in the raw water based on the electrical force, before switching to the removal mode after the static operation.

8. The water treatment system of claim 7, wherein the processor performs a control such that the second filter unit performs the preparation operation for a fourth time period being shorter than the (3-2)-th time period.

9. The water treatment system of claim 1, wherein the first filter unit and the second filter unit alternately perform the removal mode and the regeneration mode every first time period.

10. The water treatment system of claim 1, wherein a sum of the (2-1)-th time period and the (2-2)-th time period is the same as the second time period.

11. The water treatment system of claim 1, wherein the (2-2)-th time period is shorter than the (2-1)-th time period.
